(19) United States
(12) Patent Application Publication
(10) Pub. No.: US 2023/0246423 A1
(43) Pub. Date: Aug. 3, 2023

(54) INTEGRATED VCSEL DEVICE AND PHOTODIODE AND METHODS OF FORMING THE SAME

(71) Applicant: META PLATFORMS TECHNOLOGIES, LLC, Menlo Park, CA (US)

(72) Inventors: Jonatan GINZBURG, San Jose, CA (US); Rama Krishna KAMBHAMPATI, Milpitas, CA (US)

(21) Appl. No.: 17/698,630

(22) Filed: Mar. 18, 2022

Related U.S. Application Data
(60) Provisional application No. 63/305,946, filed on Feb. 2, 2022.

(51) Int. Cl. H01S 5/42; H01S 5/026; H01S 5/183

(52) U.S. Cl. CPC H01S 5/423; H01S 5/0262; H01S 5/18377

(57) ABSTRACT

Various embodiments set forth a light-emitting device, comprising a single die formed from a portion of a semiconductor substrate of a first conductivity type, a first vertical cavity surface-emitting laser (VCSEL) that is formed from a set of material layers disposed on a surface of the portion of the semiconductor substrate. and a first photodiode that is formed at the surface of the portion of the semiconductor substrate.

### CROSS-REFERENCE TO RELATED APPLICATIONS

This application claims the priority benefit of United States provisional patent application titled, “METHOD FOR FORMING AN INTEGRATED GAAS VCSEL ARRAY AND PHOTODIODE,” filed on Feb. 2, 2022, and having Ser. No. 63/305,946. The subject matter of this related application is hereby incorporated herein by reference.

### BACKGROUND

### Field of the Various Embodiments

Embodiments of this disclosure relate generally to semiconductor devices and, more specifically, to a vertical-cavity surface-emitting laser (VCSEL) device and photodiode and methods of forming the same.

### Description of the Related Art

Semiconductor devices can be a reliable, efficient, compact, and inexpensive means for generating light and detecting light, such as semiconductor lasers and photodiodes. As a result, there are many commercial, industrial, and scientific applications for light-emitting and light-detecting semiconductor devices. Such applications include telecommunications, compact disk and laser disk players, high-speed printers, and augmented reality (AR) and virtual reality (VR) systems, among others.

In many applications that rely on semiconductor lasers and photodiodes, compactness is an important consideration. For instance, AR/VR headsets are designed to perform complex operations within the confined space of a head-mounted device, such as the presentation of stereoscopic video and the precise tracking of head and eye motion. Therefore, a typical AR/VR headset includes a large number of sensors, optics, light sources, and electronic devices that must all be contained within a compact and light-weight assembly. Due to their small size and high performance and reliability, semiconductor lasers are commonly employed as light sources for the projection modules of AR/VR headsets, while photodiodes monitor the optical output of such projection modules for eye safety.

One disadvantage of conventional semiconductor lasers and photodiodes is that they can be problematically large for certain space-sensitive applications, even though the active area of such devices is quite small. For instance, an accurate, high-responsivity photodiode may have an active area that is approximately 0.1 mm in diameter, while the diameter of the entire photodiode package can be dozens of times larger (e.g., 5 mm or more). Similarly, a vertical-cavity surface-emitting laser (VCSEL) that is commonly employed as a light source for AR and VR devices can have a package diameter that is several times larger than the active area of the VCSEL. As a result, use of conventional semiconductor lasers and photodiodes can be difficult to implement in space-sensitive systems without increasing the overall size of the system.

As the foregoing illustrates, what is needed in the art are more effective techniques for fabricating semiconductor lasers and photodiodes.

### SUMMARY

One embodiment of the present disclosure sets forth a light-emitting device that includes: a single die formed from a portion of a semiconductor substrate of a first conductivity type, a first vertical cavity surface-emitting laser (VCSEL) that is formed from a set of material layers disposed on a surface of the portion of the semiconductor substrate, and a first photodiode that is formed at the surface of the portion of the semiconductor substrate.

One advantage of the design disclosed herein is that one or more semiconductor lasers and one or more photodiodes can be formed together on a single die. Consequently, a device having the functionality of a laser and the functionality of a photodiode can be implemented in a single packaged semiconductor device that is much smaller than a laser and a photodiode that are packaged separately. A further advantage of the disclosed design is that a system can be fabricated with fewer individual components, thereby reducing the potential for supply chain constraints affecting fabrication of the system. That is, there are fewer components that, due to lack of availability, can prevent fabrication of the system. These technical advantages represents one or more technological advancements over prior art approaches.

### BRIEF DESCRIPTION OF THE DRAWINGS

So that the manner in which the above recited features of the various embodiments can be understood in detail, a more particular description of the disclosed concepts, briefly summarized above, may be had by reference to various embodiments, some of which are illustrated in the appended drawings. It is to be noted, however, that the appended drawings illustrate only typical embodiments of the disclosed concepts and are therefore not to be considered limiting of scope in any way, and that there are other equally effective embodiments.

FIG. 1 is a perspective view of an integrated semiconductor device, according to various embodiments.

FIG. 2 is a cross-sectional view of the integrated semiconductor device of FIG. 1 taken at section A-A in FIG. 1, according to various embodiments.

FIG. 3 sets forth a flowchart of method steps for fabricating an integrated semiconductor device, according to various embodiments.

FIGS. 4A-4M schematically illustrate various steps of fabrication process 300, according to various embodiments.

FIG. 5 schematically illustrates an integrated semiconductor device after packaging, according to various embodiments.

For clarity, identical reference numbers have been used, where applicable, to designate identical elements that are common between figures. It is contemplated that features of one embodiment may be incorporated in other embodiments without further recitation.

### DETAILED DESCRIPTION

In the following description, numerous specific details are set forth to provide a more thorough understanding of the various embodiments. However, it is apparent to one of skilled in the art that the disclosed concepts may be practiced without one or more of these specific details.

### Configuration Overview

Embodiments described herein may include or be implemented in conjunction with an artificial reality system. Artificial reality is a form of reality that has been adjusted in some manner before presentation to a user, which may include, for example, a virtual reality (VR) system, an augmented reality (AR) system, a mixed reality (MR) system, a hybrid reality system, or some combination and/or derivatives thereof. Artificial reality content may include, without limitation, completely generated content or generated content combined with captured (e.g., real-world) content. The artificial reality content may include, without limitation, video, audio, haptic feedback, or some combination thereof. The artificial reality content may be presented in a single channel or in multiple channels (such as stereo video that produces a three-dimensional effect to the viewer). Additionally, in some embodiments, artificial reality systems may also be associated with applications, products, accessories, services, or some combination thereof, that are used to, e.g., create content in an artificial reality system and/or are otherwise used in (e.g., perform activities in) an artificial reality system. The artificial reality system may be implemented on various platforms, including a head-mounted display (HMD) connected to a host computer system, a standalone HMD, a mobile device or computing system, or any other hardware platform capable of providing artificial reality content to one or more viewers.

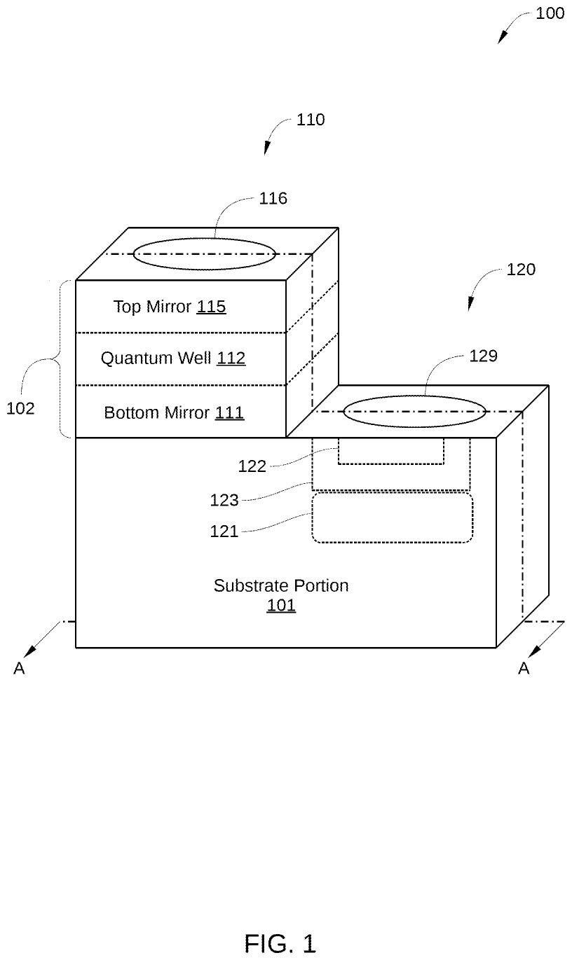

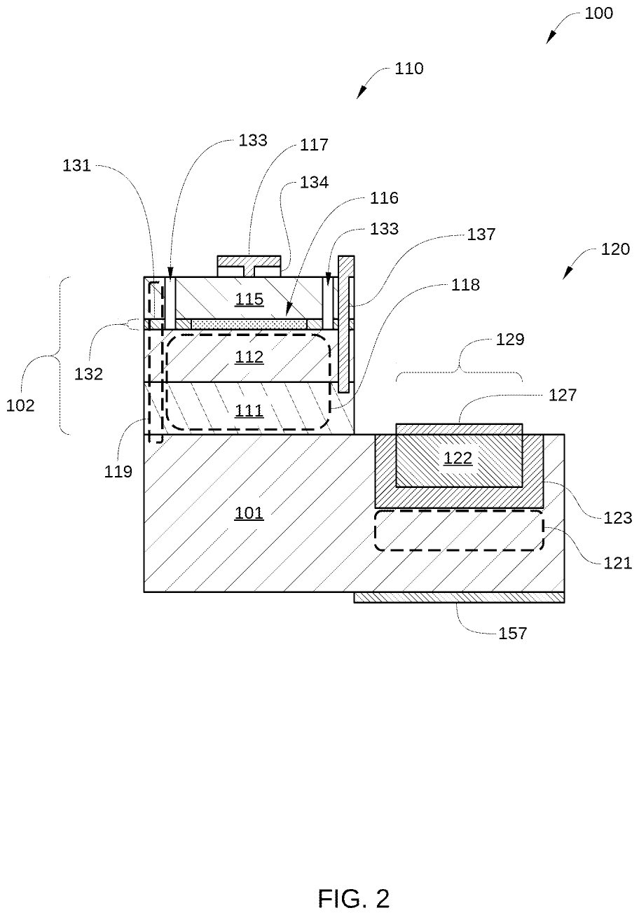

FIG. 1 is a perspective view of an integrated semiconductor device 100, according to various embodiments, and FIG. 2 is a cross-sectional view of integrated semiconductor device 100 taken at section A-A in FIG. 1, according to various embodiments. In the embodiment illustrated in FIGS. 1 and 2, integrated semiconductor device 100 includes a vertical-cavity surface-emitting laser (VCSEL) 110 and a photodiode 120 formed on a substrate portion 101. Substrate portion 101 is diced or otherwise separated from a semiconductor substrate (not shown) after formation of VCSEL 110 and photodiode 120. Thus, integrated semiconductor device 100 is configured as a single semiconductor die that can be packaged as a single device that includes the functionality of a laser and a photodiode.

In the embodiment illustrated in FIG. 1, integrated semiconductor device 100 includes a single VCSEL 110 and a single photodiode 120. In other embodiments, integrated semiconductor device 100 may include multiple VCSELs configured as a linear array or two-dimensional array. Additionally or alternatively, in some embodiments, integrated semiconductor device 100 includes multiple photodiodes 120. In such embodiments, the multiple photodiodes can be configured as a linear array, a two-dimensional array, or dispersed within an array of multiple VCSELs 110. For example, in some embodiments, integrated semiconductor device 100 includes an array of hundreds or thousands of individual VCSELs 110. In some embodiments, each VCSEL 110 included in the array of VCSELs 110 is electrically coupled together by at least one metal trace included in integrated semiconductor device 100, such as top metallization 117. Thus, in such embodiments, each VCSEL 110 in the array can be controlled together simultaneously with a single input signal via the metal trace. Similarly, in some embodiments, each photodiode 120 in an array of multiple photodiodes 120 is electrically coupled together by at least one metal trace included in integrated semiconductor device 100, such as top metallization 127. Thus, in such embodiments, the output from each photodiode 120 in an array of multiple photodiodes 120 can be communicatively coupled together into a single output signal. Alternatively, in some embodiments, each photodiode 120 in an array of multiple photodiodes 120 is electrically coupled to a different metal trace included in integrated semiconductor device 100, such as top metallization 127, so that the output from each photodiode 120 in the array of multiple photodiodes 120 provides a separate output signal. For clarity, top metallization 117 and 127 are omitted from FIG. 1 and only shown in FIG. 2.

VCSEL 110 is a semiconductor laser that, like a light-emitting diode, can convert electrical energy into light. Through the process of stimulated emission, VCSEL 110 generates light with the same phase, coherence, and wavelength. More specifically, VCSEL 110 is a surface-emitting lasers (SELs), which outputs radiation perpendicular to the plane of the semiconductor substrate from which VCSEL 110 is formed. For AR and VR devices in particular, VCSELs are commonly employed as a light source. In a VCSEL, the “vertical” direction indicates a direction perpendicular to the plane of the semiconductor substrate on which the constituent layers are epitaxially grown or deposited, where “up” refers to the direction that such layers are grown or deposited and down refers to the direction toward the semiconductor substrate. VCSELs have many advantages over edge-emitting lasers, such as low threshold current, single longitudinal mode, a circular output beam profile, ease of fiber coupling, and scalability to monolithic laser arrays. For example, a large number of VCSELs (e.g., hundreds or thousands) can be fabricated on a single semiconductor die, such as substrate portion 101.

In the embodiment illustrated in FIGS. 1 and 2, VCSEL 110 is configured as a single-junction VCSEL. As such, VCSEL 110 is formed from a set of material layers 102 that are disposed on substrate portion 101 and include a bottom mirror layer 111, a top mirror layer 115, and a single quantum well layer 112. Bottom mirror layer 111 and top mirror layer 115 are configured to reflect light generated in an active region of VCSEL 110, and are oriented substantially parallel to the plane of substrate portion 101. In some embodiments, bottom mirror layer 111 and top mirror layer 115 are configured as distributed Bragg reflectors, and include a plurality of material layers (not shown) with alternating high and low refractive indices. In such embodiments, when material layers included in bottom mirror layer 111 or top mirror layer 115 have a thickness of a quarter of the laser wavelength, very high intensity reflectivities on the order of 99% or above can be realized. Quantum well layer 112 forms an active region of VCSEL 110. Thus, a portion of quantum well layer 112 is disposed in a laser cavity (or optical cavity) 118 (dashed lines) of VCSEL 110. Laser cavity 118 for VCSEL 110 is typically bounded by bottom mirror layer 111, top mirror layer 115, and resistive isolation regions 119. Generally, bottom mirror layer 111 is a first conductivity type (e.g., an n-type semiconductor material) and top mirror layer 115 is a second conductivity type (e.g., a p-type semiconductor material).

In alternative embodiments, VCSEL 110 is configured as a multi-junction VCSEL. In such embodiments, VCSEL 110 includes multiple quantum well layers and a tunnel junction layer that is disposed between the quantum well layers that are all disposed in laser cavity 118.

As shown in FIG. 2, top mirror layer 115 includes an aperture 116 through which light is emitted from VCSEL 110. In the embodiment illustrated in FIG. 2, aperture 116 is an oxide aperture that is formed or defined by one or more oxidized portions 151 (cross-hatched) of an oxidizing layer 132 that is included in top mirror layer 115. That is, aperture 116 corresponds to the portions of oxidizing layer 132 that are not oxidized. In such embodiments, oxidizing layer 132 may be exposed to an oxidation process via one or more oxidation trenches 133 that are formed in set of material layers 102 prior to the oxidation process. In other embodiments, aperture 116 can be formed by other conventional techniques, such as techniques that lower the reflectivity of the exit mirror (in this case top mirror layer 115) relative to the opposing mirror (in this case bottom mirror layer 111).

To enable operation of VCSEL 110, VCSEL 110 includes top metallization 117, which is electrically coupled to top mirror layer 115, and a bottom metallization 157, which is electrically coupled to substrate portion 101. Further, in the embodiment illustrated in FIG. 2, top metallization 117 is shown formed on an ohmic contact 134. In such embodiments, ohmic contact 134 is configured to enable a suitable metal-semiconductor ohmic contact to be formed between top metallization 117 and a semiconductor layer of set of material layers 102, such as top mirror layer 115.

In the embodiment illustrated in FIGS. 1 and 2, photodiode 120 is configured as a P-I-N photodiode. As such, photodiode 120 includes a first semiconductor region 121 of a first conductivity (e.g., an n-type semiconductor material), a second semiconductor region 122 of a second conductivity type (e.g., a p-type semiconductor material), and an intrinsic semiconductor region 123 that is disposed between first semiconductor region 121 and second semiconductor region 122.

To enable operation of photodiode 120, photodiode 120 includes top metallization 127, which is electrically coupled to second semiconductor region 122, and bottom metallization 157. In some embodiments, top metallization 127 is configured as a metal trace (or a trace that includes some other conductive material) that transmits an output signal from photodiode 120. Top metallization 127 forms or includes a contact that is electrically coupled to second semiconductor region 122. In the embodiment illustrated in FIGS. 1 and 2, top metallization 127 is shown covering an active region 129 of photodiode 120. In practice, top metallization 127 typically covers a small portion of active region 129.

According to various embodiments, first semiconductor region 121 is formed from or includes a portion of substrate portion 101, which is the semiconductor substrate on which VCSEL 110 is also formed. Similarly, in some embodiments, second semiconductor region 122 and intrinsic semiconductor region 123 are each formed from a different portion of substrate portion 101. In such embodiments, intrinsic semiconductor region 123, which is an intrinsic semiconductor type, is formed from a portion of substrate portion 101, which is a first conductivity type. Further, in such embodiments, second semiconductor region 122, which is a second conductivity type, is formed from a portion intrinsic semiconductor region 123, which is an intrinsic semiconductor type. In such embodiments, intrinsic semiconductor region 123 is formed from a portion of substrate portion 101 via a first ion implantation process (described below), and second semiconductor region 122 is formed from a portion of intrinsic semiconductor region 123 via a second ion implantation process (described below) that is performed after the first ion implantation process.

Alternatively, in some embodiments, photodiode 120 is configured as a P-N photodiode. In such embodiments, photodiode 120 includes first semiconductor region 121 of the first conductivity type and second semiconductor region 122 the second conductivity type, and does not include intrinsic semiconductor region 123.

In an example embodiment, top mirror layer 115 has a thickness on the order of about 2-3 microns and includes a plurality (e.g., 30 pairs) of alternating layers of gallium-arsenide (GaAs) and p-doped aluminum-gallium-arsenide (AlGaAs). In the example embodiment quantum well layer 112 includes a layer of indium-gallium-arsenide (InGaAs) having a thickness on the order of about 10-100 nanometers. In the example embodiment, ohmic contact 134 includes a highly p-doped GaAs contact layer. In the example, substrate portion 101 includes a portion of a GaAs wafer, and bottom mirror layer 111 has a thickness on the order of about 2-3 microns and includes a plurality (e.g., 15 pairs) of alternating layers of GaAs and n-doped aluminum-arsenide (AlAs). Thus, in the example embodiment, top mirror layer 115 is of a first semiconductor type and bottom mirror layer 111 is of a second semiconductor type.

In the example embodiment, photodiode 120 is configured to generate a signal in response to incident light having a wavelength between about 800 nm and 900 nm. Further, intrinsic semiconductor region 123 includes one or more implant species that cause the portion of substrate portion 101 corresponding to intrinsic semiconductor region 123 to change from the first conductivity type to an intrinsic semiconductor type. For example, in some embodiments, the implant species includes boron ions. In addition, second semiconductor region 122 includes implant species that cause the portion of intrinsic semiconductor region 123 corresponding to second semiconductor region 122 to change from an intrinsic semiconductor type to the second conductivity type. For example, in some embodiments, the implant species includes zinc ions, which is an impurity that acts as a P dopant in GaAs.

In the example embodiment described above, material layers on the bottom side (e.g., the side closest to substrate portion 101) of an active region of VCSEL 110 are described being doped to have a first conductivity type (e.g., n-type), and material layers on the top side (e.g., the side farthest from substrate portion 101) of the active region VCSEL 110 are described being doped to have a second conductivity type (e.g., p-type). In other embodiments, an opposing doping scheme may be employed for both VCSEL and photodiode 120. Alternatively, or additionally, one or more layers included in set of material layers 102 may be undoped, and/or more heavily doped than in the exemplary description above.

### Fabrication Process for an Integrated Semiconductor Device

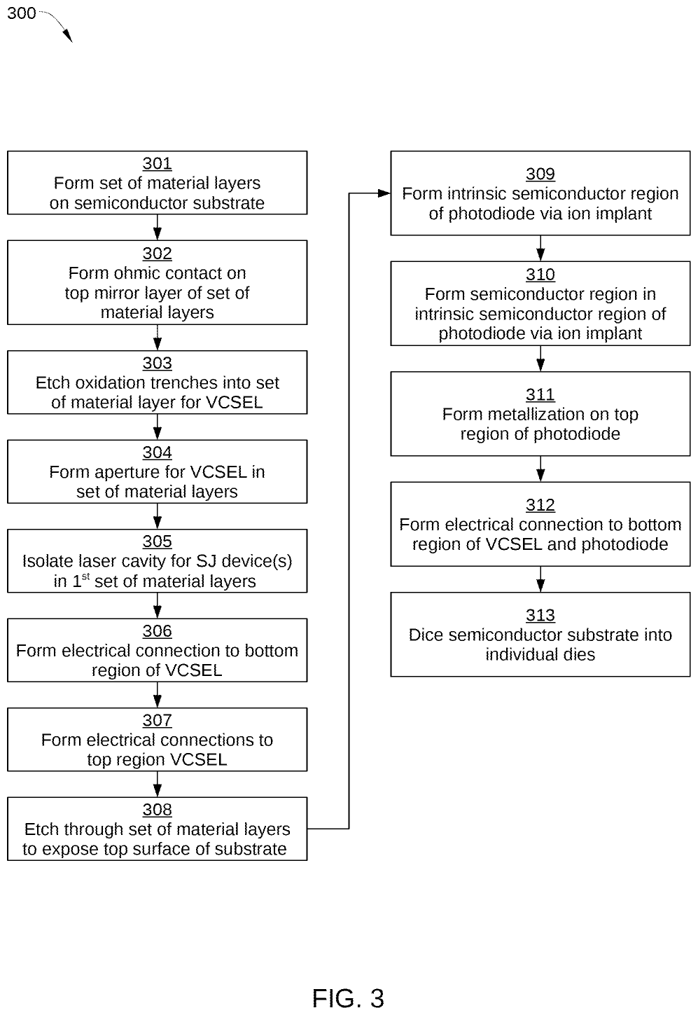

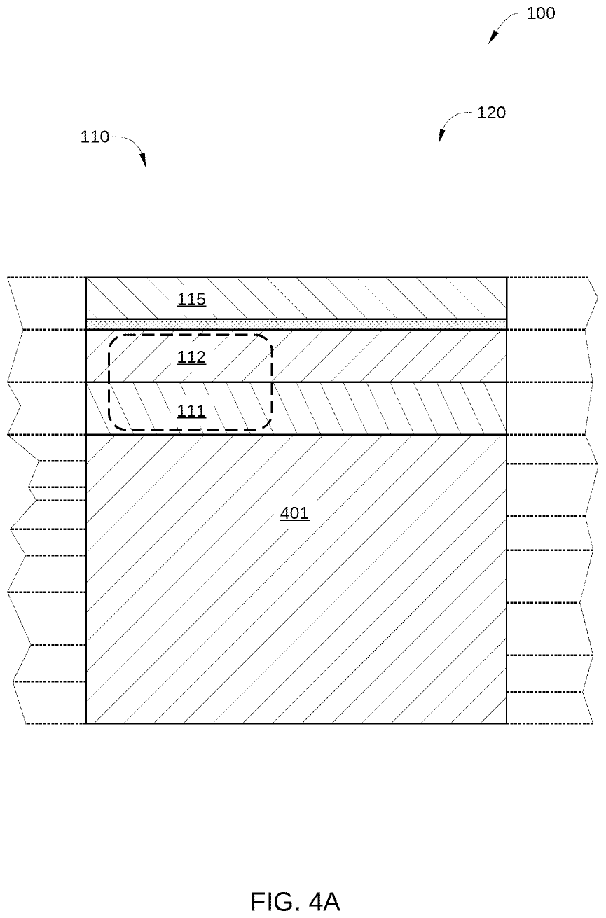

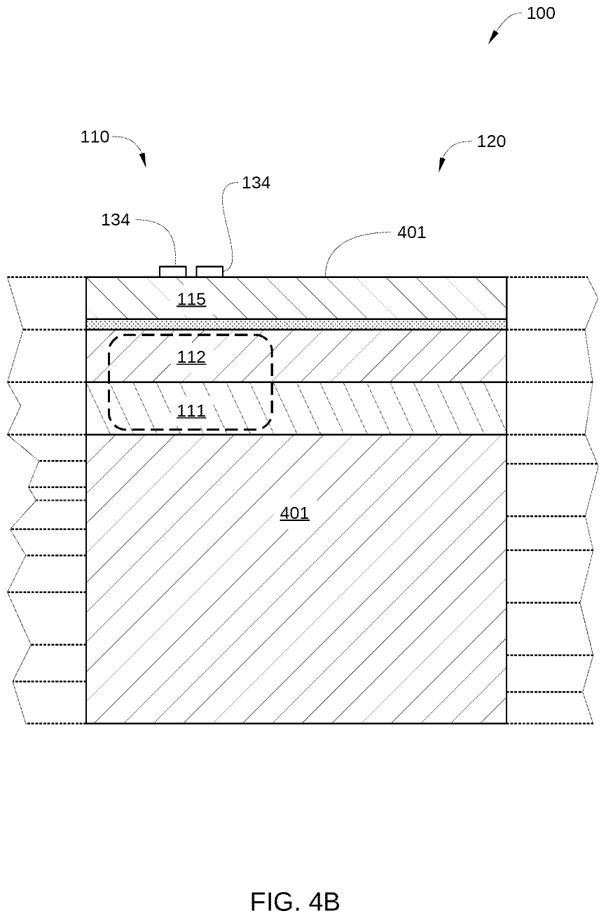

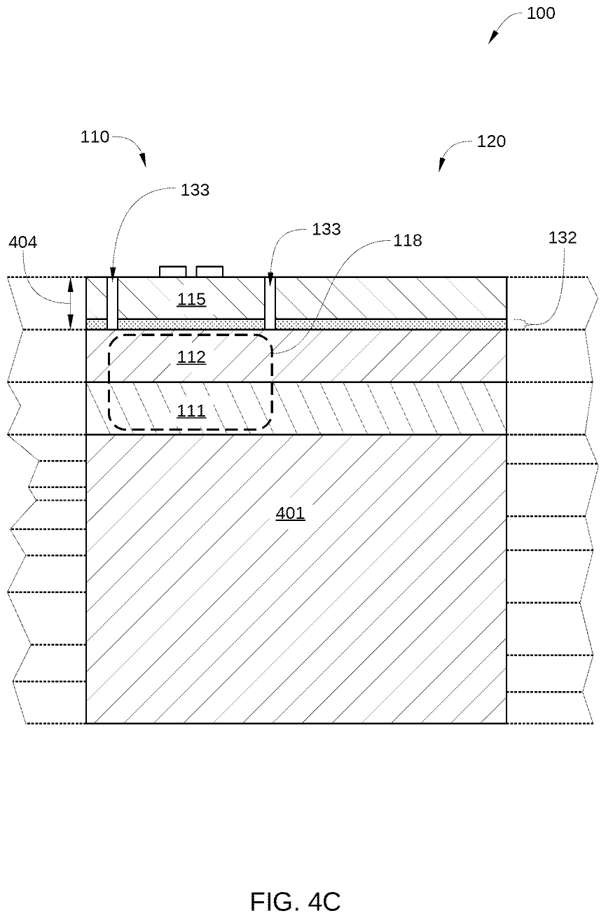

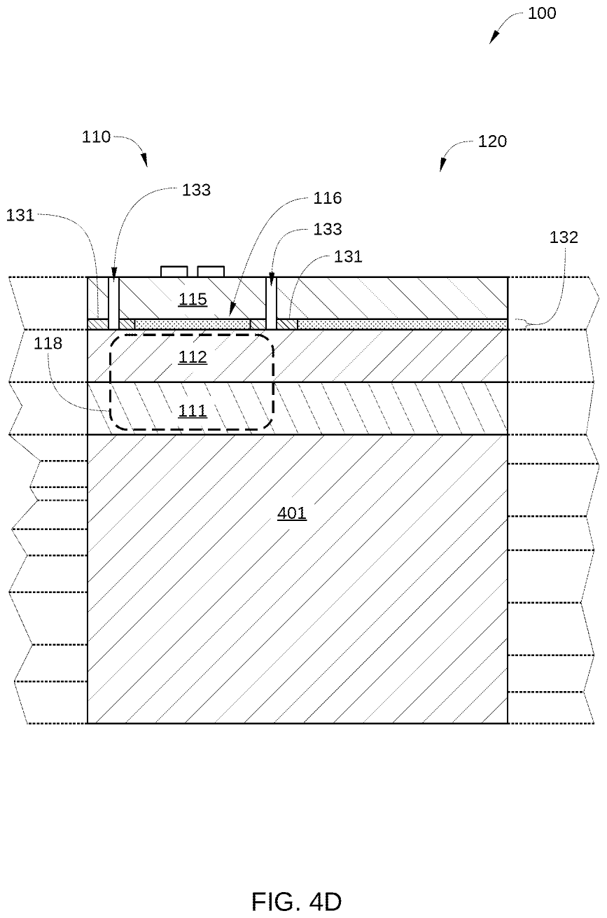

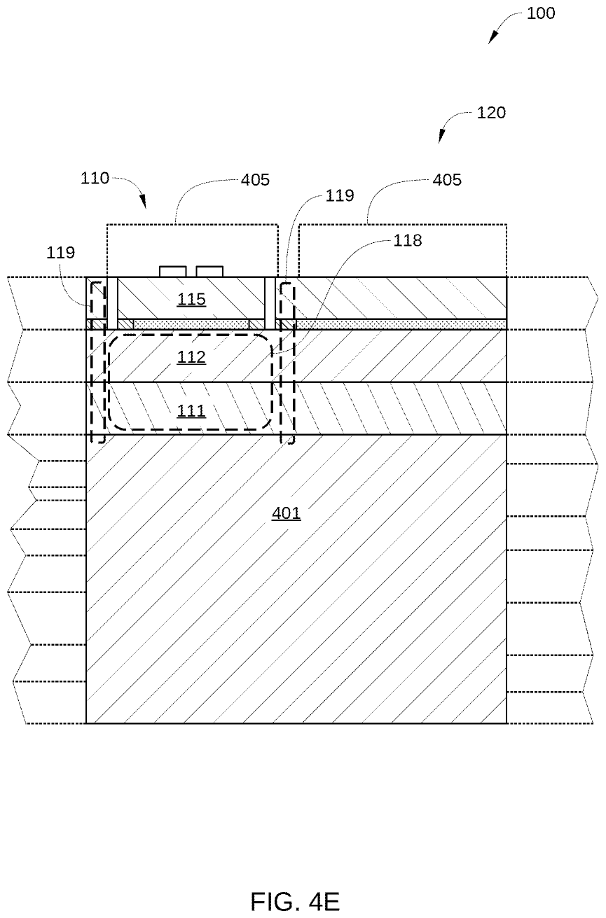

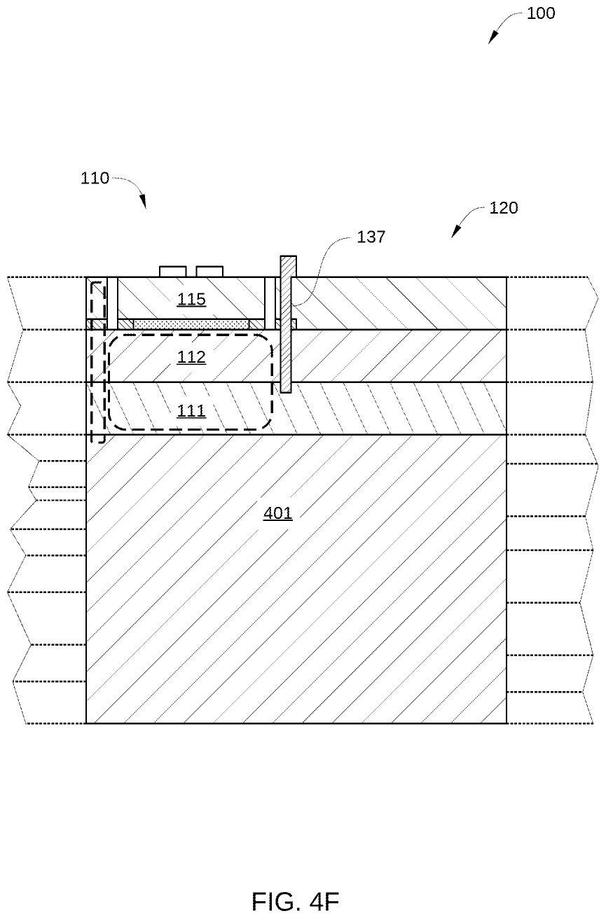

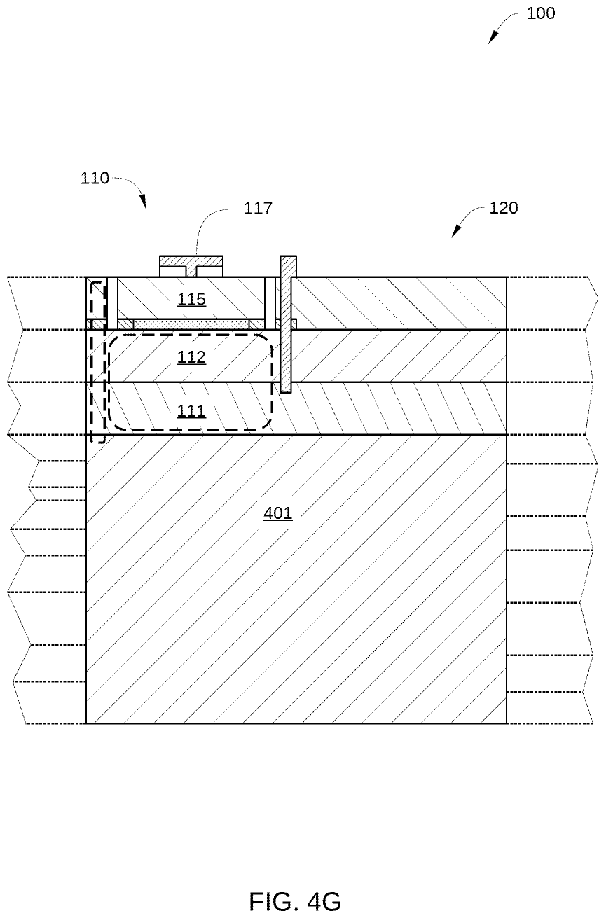

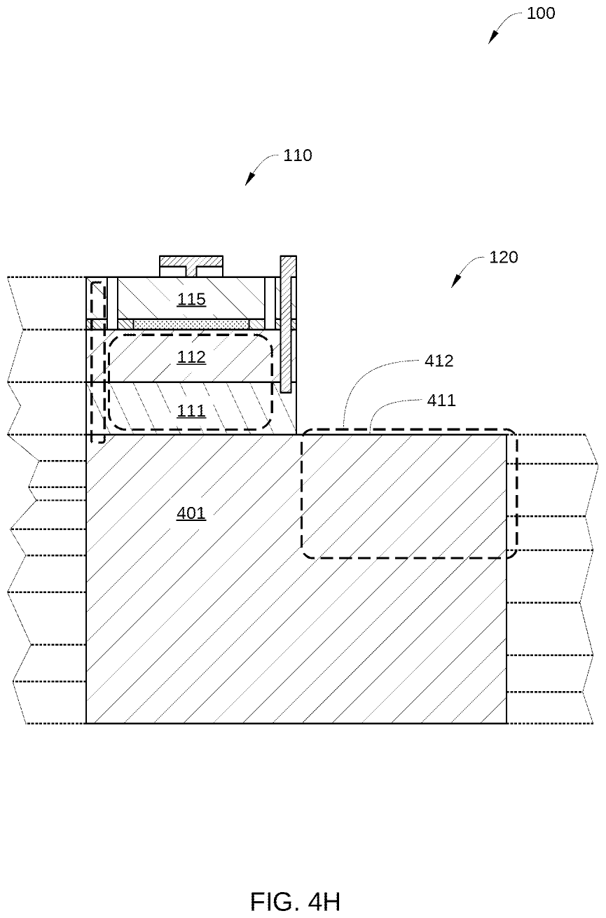

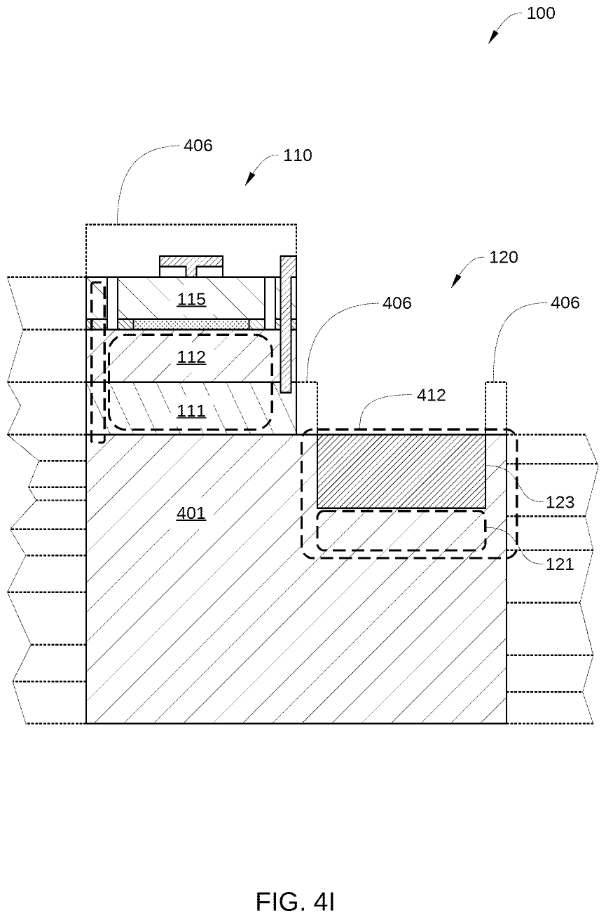

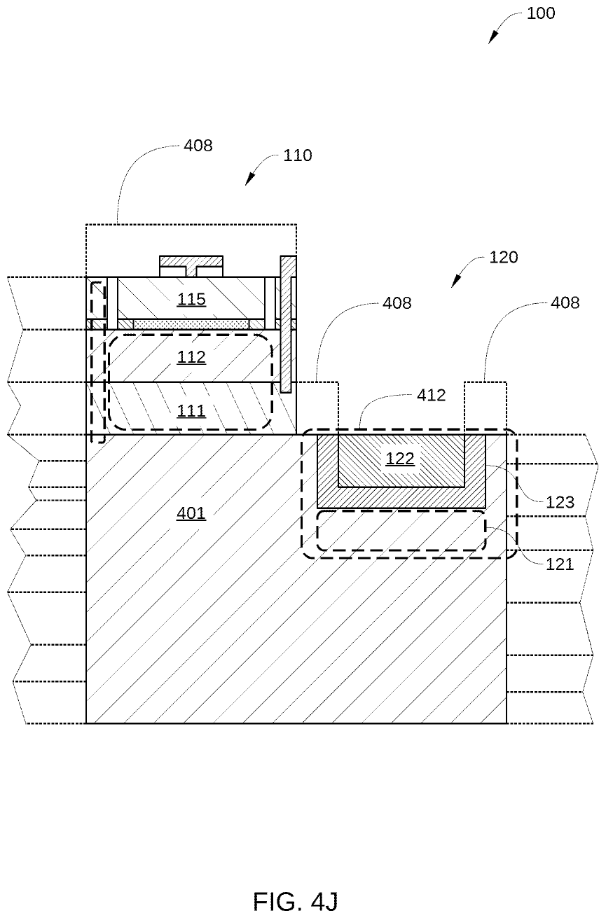

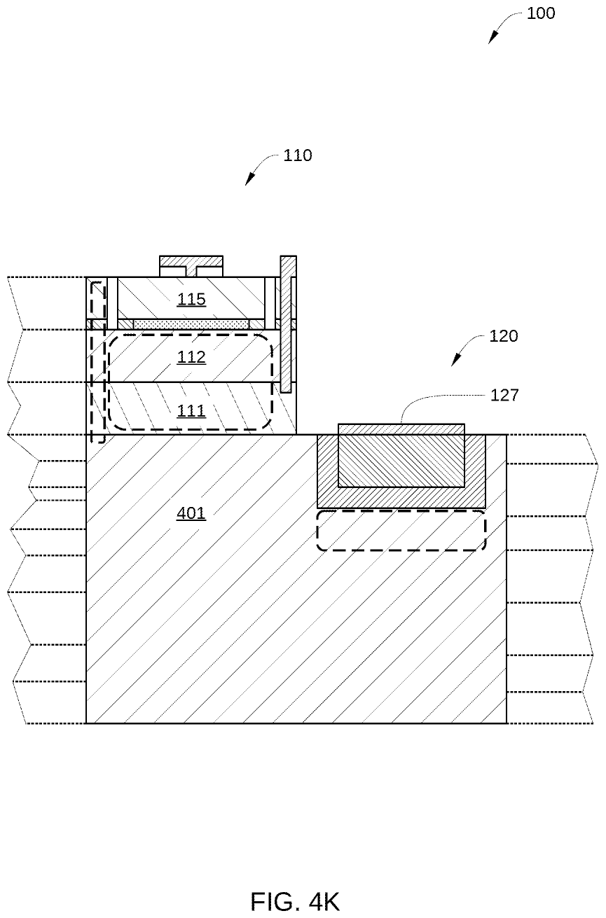

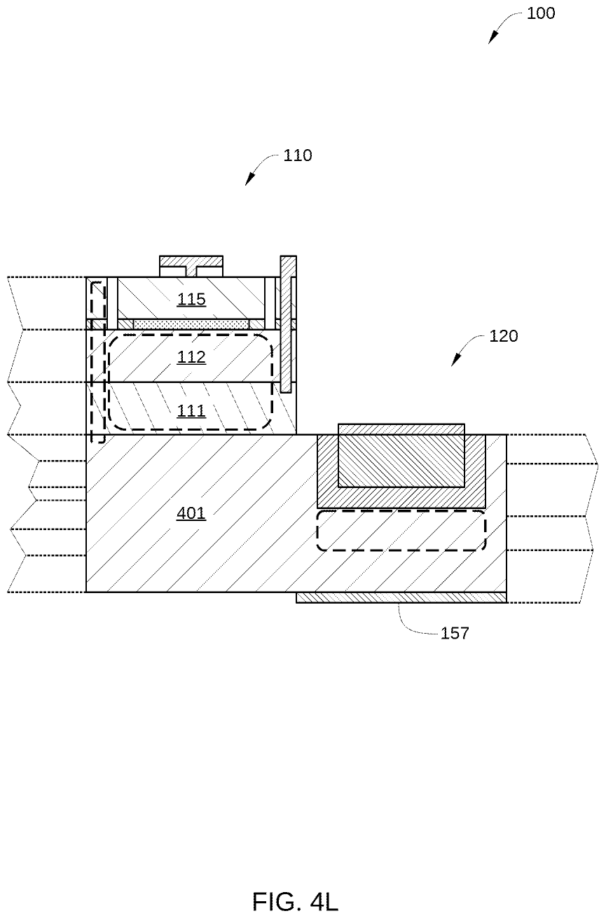

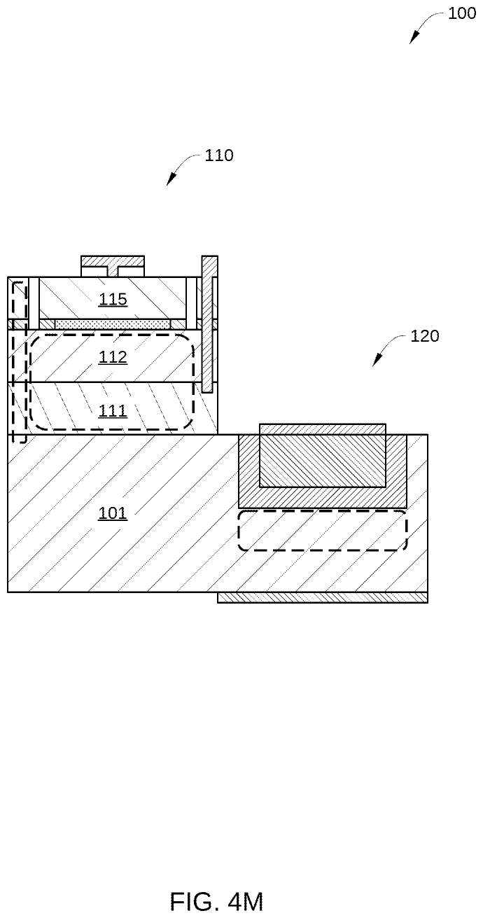

FIG. 3 sets forth a flowchart of method steps for fabricating an integrated semiconductor device, according to various embodiments. Although the method steps of a fabrication process 300 are described in conjunction with the system of FIGS. 1 and 2, persons skilled in the art will understand that any system configured with a semiconductor laser and a photodiode formed on a single die is within the scope of the embodiments. FIGS. 4A-4M schematically illustrate various steps of fabrication process 300, according to various embodiments.

As shown, fabrication process 300 begins at step 301, where set of material layers 102 is formed on a semiconductor substrate 401, as shown in FIG. 4A. In some embodiments, semiconductor substrate 401 is a GaAs wafer or other suitable semiconductor wafer that can subsequently be diced into individual dies, such as substrate portion 101 in FIGS. 1 and 2. In some embodiments, one or more of the layers included in set of material layers 102 is formed via epitaxial growth on semiconductor substrate 401. Alternatively, in some embodiments, one or more layers formed on semiconductor substrate 401 are formed via any other technical feasible approach suitable for fabricating a light-emitting device. In the embodiment illustrated in FIG. 4A, set of material layers 102 includes bottom mirror layer 111, top mirror layer 115, and a single quantum well layer 112. Further, in some embodiments, top mirror layer 115 includes an oxidizing layer 132.

In step 302, ohmic contact 134 is formed on a top region of set of material layers 102, such as an exposed surface 401 of top mirror layer 115, as shown in FIG. 4B. Thus, ohmic contact 134 is formed for the as-yet unformed VCSEL 110. As described above, ohmic contact 134 is an electrical connection that includes a suitable metal-semiconductor ohmic contact for enabling a metal trace, such as top metallization 117 (described below in conjunction with FIG. 4G), to be electrically coupled to VCSEL 110. In some embodiments, ohmic contact includes a thin metal-containing layer that is selected based on the composition of the top region of second set of material layers 103. In some embodiments, an anneal process is performed on the thin metal layer in step 302 to produce a targeted semiconductor-metal bond.

In step 303, oxidation trenches 133 are formed in set of material layers 102, as shown in FIG. 4C. A depth 404 of oxidation trenches 133 is selected so that at least a portion of oxidizing layer 132 is exposed. Any technically feasible masking and etching technique can be employed in step 303 to form oxidation trenches 133, including reactive ion etching (RIE).

In step 304, an aperture 116 is formed in set of material layers 102, as shown in FIG. 4D. Thus, aperture 116 is formed for VCSEL 110 that is included in integrated semiconductor device 100. In embodiments in which aperture 116 is an oxide aperture, step 304 includes an oxidation process in which oxidized portions 131 of oxidizing layer 132 are formed using oxidation trenches 133.

In step 305, laser cavities 118 in set of material layers 102 are isolated, as shown in FIG. 4E. Specifically, in the embodiment illustrated in FIG. 4E, an ion implantation process is performed on unmasked regions of set of material layers 102. In such embodiments, a crystal lattice (not shown) of a portion of at least one semiconductor layer included in the set of material layers (e.g., top mirror layer 115) is damaged by the ion implantation process. As a result, electrical resistivity is increased in the portion of the at least one semiconductor layer, and resistive isolation regions 119 proximate laser cavities 118 are formed. Thus, laser cavity 118 included in VCSEL 110 is an isolated laser cavity from which current is resistively isolated from adjacent laser cavities 118. For reference, ion implant masks 405 (dashed lines) are also shown in FIG. 4E, and indicate regions of set of material layers 102 that are not altered in step 305.

In step 306, first electrical connections (e.g., bottom contacts 137) are formed that connect bottom mirror layer 111 to a top metallization, as shown in FIG. 4F. In some embodiments, the first electrical connections are formed in multiple process steps (e.g., via etching and via fill) prior to the formation of second electrical connections (described below). Alternatively, in some embodiments, step 306 is performed after step 307, and the first electrical connections are formed after the second electrical connections.

In step 307, second electrical connections are formed on a top region of set of material layers 102, as shown in FIG. 4G. In the embodiment illustrated in FIG. 4G, second electrical connections are formed that contact ohmic contact 134 (e.g., top metallization 117). Thus, in step 307, electrical connections to a top region of VCSEL 110 are formed. In some embodiments, the formation of the second electrical connections is performed in a metal deposition process, such as electroplating, e-beam deposition, or any other technically feasible metal deposition technique.

In step 308, a portion of set of material layers 102 is etched to expose a surface 411 of substrate portion 101, as shown in FIG. 4H. Thus, an edge region 412 of substrate portion 101 is exposed. As described below, photodiode 120 is then formed at edge region 412 of substrate portion 101. Any technically feasible masking and etching technique can be employed in step 308 to remove the portion of set of material layers 102, including RIE.

In step 309, intrinsic semiconductor region 123 is formed from a portion of substrate portion 101 via a first ion implantation process, as shown in FIG. 4I. In the first ion implantation process, an implant species is employed that causes the portion of edge region 412 corresponding to intrinsic semiconductor region 123 to change from the first conductivity type to an intrinsic semiconductor type. For example, in some embodiments, the implant species includes boron ions. For reference, ion implant masks 406 (dashed lines) are also shown in FIG. 4I, and indicate regions of VCSEL 110 and edge region 412 that are not altered in step 309.

In step 310, second semiconductor region 122 is formed from a portion of intrinsic semiconductor region 123 via a first second ion implantation process, as shown in FIG. 4J. In the second ion implantation process, an implant species is employed that causes the portion of intrinsic semiconductor region 123 corresponding to second semiconductor region 122 to change from an intrinsic semiconductor type to the second conductivity type. For example, in some embodiments, the implant species includes zinc ions. For reference, ion implant masks 408 (dashed lines) are also shown in FIG. 4J, and indicate regions of VCSEL 110 and edge region 412 that are not altered in step 310.

In step 311, top metallization 127 is formed on a top region of photodiode 120, as shown in FIG. 4K. Thus, in step 311, an electrical connection is formed a portion of photodiode 120 of the second conductivity type, such as second semiconductor region 122. In the embodiment illustrated in FIG. 4K, top metallization 127 is formed directly on second semiconductor region 122. In other embodiments, top metallization 127 is formed with well-known techniques so that an electrical connection that includes a suitable metal-semiconductor ohmic contact formed with second semiconductor region 122. For example, in such embodiments, top metallization 127 is formed on an ohmic contact material. In some embodiments, the formation of top metallization 127 is performed in a metal deposition process, such as electroplating, e-beam deposition, or any other technically feasible metal deposition technique.

In step 312, an electrical connection to a bottom region of VCSEL 110 is formed, such as a bottom contact. For example, in the embodiment illustrated in FIG. 4L, bottom metallization 157 is formed on and electrically coupled to a bottom surface of semiconductor substrate 401 after semiconductor substrate 401 is polished down to a final thickness. Bottom metallization 157 also acts as a bottom contact for photodiode 120.

In step 313, substrate portion 101, along with VCSEL 110 and photodiode 120, is separated from semiconductor substrate 400, as shown in FIG. 4M.

By way of example, in the embodiments described above, VCSEL 110 is configured to emit laser light from a top surface. In other embodiments, VCSEL 110 can be configured to emit laser light from a bottom surface, for example through substrate portion 101.

### Integrated Semiconductor Device in Package

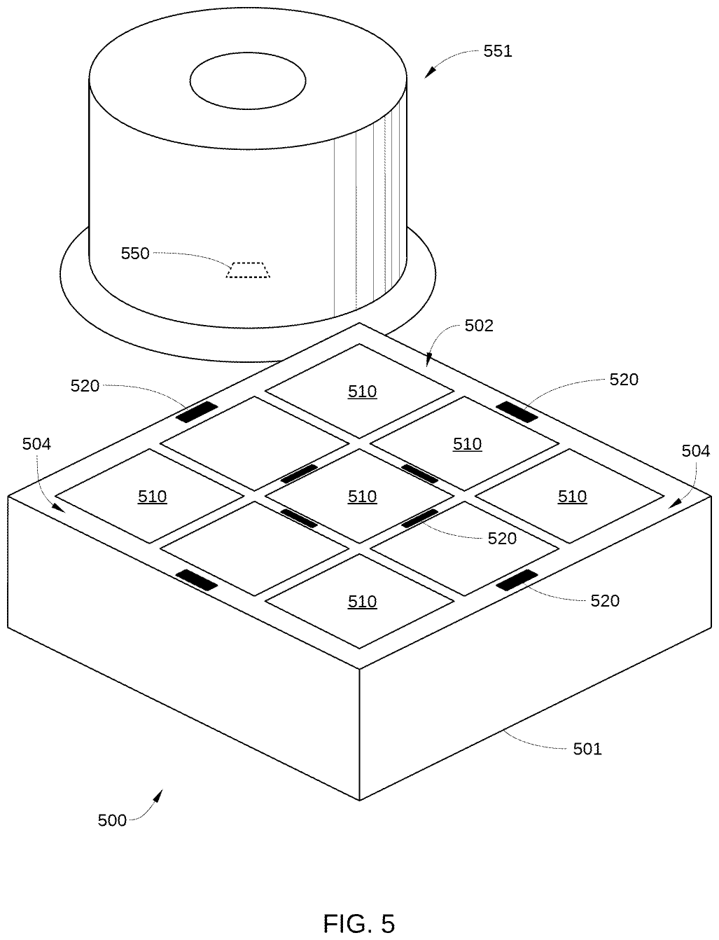

In embodiments described above, an integrated semiconductor device is depicted to include a single semiconductor laser and a single photodiode that are formed on a single die. In other embodiments, an integrated semiconductor device includes an array of multiple semiconductor lasers and/or photodiodes that are formed on a single die. One such embodiment is described below in conjunction with FIG. 5.

FIG. 5 schematically illustrates an integrated semiconductor device 500 after packaging, according to various embodiments. As shown, integrated semiconductor device 500 is enclosed in a package 501 and includes a plurality of VCSELs 510 that are arranged in an array 502. Integrated semiconductor device 500 further includes one or more photodiodes 520. VCSELs 510 and photodiodes 520 are formed on a single die (not visible in FIG. 5) similar to VCSEL 110 and photodiode 120 of FIG. 1.

Because photodiodes 520 are formed on the same die as VCSELs 510, photodiodes 520 can be positioned on one or more edge regions 504 of array 502 and/or within array 502, such as at a center point of array 502 and/or between individual VCSELs 510. Thus, the functionality of photodiodes 520 is incorporated into integrated semiconductor device 500 without significantly increasing the total size of integrated semiconductor device 500 after packaging.

For reference, a conventional photodiode 550 that is enclosed in an individual package 551 is also shown in FIG. 5. As shown, individual package 551 for a conventional photodiode 550 can be approximately as large as integrated semiconductor device 500, and multiple individual packages 551 placed around the periphery of integrated semiconductor device 500 can be significantly larger than integrated semiconductor device 500. It is noted that the relatively large package size of conventional semiconductor lasers and photodiodes can greatly limit where such electro-optical devices can be placed within an assembly. For instance, in the case of an AR/VR headset, a photodiode monitoring the output of a laser-based projection module cannot be positioned any closer to the laser than is allowed by the photodiode package. Furthermore, the integration of individually packaged photodiodes and lasers into a laser-based projection module increases the size and complexity of the module, which is highly undesirable.

One advantage of the techniques disclosed design disclosed herein is that one or more semiconductor lasers and one or more photodiodes can be formed together on a single die. Consequently, a device having the functionality of a laser and the functionality of a photodiode can be implemented in a single packaged semiconductor device that is much smaller than a laser and a photodiode that are packaged separately. A further advantage of the disclosed design is that a system can be fabricated with fewer individual components, thereby reducing the potential for supply chain constraints affecting fabrication of the system. That is, there are fewer components that, due to lack of availability, can prevent fabrication of the system. These technical advantages represents one or more technological advancements over prior art approaches

[Claim combinations inserted by Artegis here at time of filing].

Any and all combinations of any of the claim elements recited in any of the claims and/or any elements described in this application, in any fashion, fall within the contemplated scope of the present disclosure and protection.

The foregoing description of the embodiments of the disclosure has been presented for the purpose of illustration; it is not intended to be exhaustive or to limit the disclosure to the precise forms disclosed. Persons skilled in the relevant art can appreciate that many modifications and variations are possible in light of the above disclosure.

Some portions of this description describe the embodiments of the disclosure in terms of algorithms and symbolic representations of operations on information. These algorithmic descriptions and representations are commonly used by those skilled in the data processing arts to convey the substance of their work effectively to others skilled in the art. These operations, while described functionally, computationally, or logically, are understood to be implemented by computer programs or equivalent electrical circuits, microcode, or the like. Furthermore, it has also proven convenient at times, to refer to these arrangements of operations as modules, without loss of generality. The described operations and their associated modules may be embodied in software, firmware, hardware, or any combinations thereof.

Any of the steps, operations, or processes described herein may be performed or implemented with one or more hardware or software modules, alone or in combination with other devices. In one embodiment, a software module is implemented with a computer program product comprising a computer-readable medium containing computer program code, which can be executed by a computer processor for performing any or all of the steps, operations, or processes described.

Embodiments of the disclosure may also relate to an apparatus for performing the operations herein. This apparatus may be specially constructed for the required purposes, and/or it may comprise a general-purpose computing device selectively activated or reconfigured by a computer program stored in the computer. Such a computer program may be stored in a non-transitory, tangible computer readable storage medium, or any type of media suitable for storing electronic instructions, which may be coupled to a computer system bus. Furthermore, any computing systems referred to in the specification may include a single processor or may be architectures employing multiple processor designs for increased computing capability.

Embodiments of the disclosure may also relate to a product that is produced by a computing process described herein. Such a product may comprise information resulting from a computing process, where the information is stored on a non-transitory, tangible computer readable storage medium and may include any embodiment of a computer program product or other data combination described herein.

Finally, the language used in the specification has been principally selected for readability and instructional purposes, and it may not have been selected to delineate or circumscribe the inventive subject matter. It is therefore intended that the scope of the disclosure be limited not by this detailed description, but rather by any claims that issue on an application based hereon. Accordingly, the disclosure of the embodiments is intended to be illustrative, but not limiting, of the scope of the disclosure, which is set forth in the following claims.

The descriptions of the various embodiments have been presented for purposes of illustration, but are not intended to be exhaustive or limited to the embodiments disclosed. Many modifications and variations is apparent to those of ordinary skill in the art without departing from the scope and spirit of the described embodiments.

Aspects of the present embodiments may be embodied as a system, method, or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a ““module” or “system.” Furthermore, aspects of the present disclosure may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It is understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine. The instructions, when executed via the processor of the computer or other programmable data processing apparatus, enable the implementation of the functions/acts specified in the flowchart and/or block diagram block or blocks. Such processors may be, without limitation, general purpose processors, special-purpose processors, application-specific processors, or field-programmable gate arrays.

The flowchart and block diagrams in the figures illustrate the architecture, functionality, and operation of possible implementations of systems, methods, and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

While the preceding is directed to embodiments of the present disclosure, other and further embodiments of the disclosure may be devised without departing from the basic scope thereof, and the scope thereof is determined by the claims that follow.

What is claimed is:

1. A light-emitting device, comprising:
a single die formed from a portion of a semiconductor substrate of a first conductivity type;
a first vertical cavity surface-emitting laser (VCSEL) that is formed from a set of material layers disposed on a surface of the portion of the semiconductor substrate; and
a first photodiode that is formed at the surface of the portion of the semiconductor substrate.

2. The light-emitting device of claim 1, wherein the first photodiode includes:
a first semiconductor region of the first conductivity type that includes a portion of the semiconductor substrate;
a second semiconductor region of a second conductivity type that is disposed on an intrinsic semiconductor region; and
the intrinsic semiconductor region that is disposed between the first semiconductor region and the second semiconductor region.

3. The light-emitting device of claim 2, wherein the intrinsic semiconductor region is formed from an edge region of the portion of the semiconductor substrate.

4. The light-emitting device of claim 2, further comprising a contact that is electrically coupled to the second semiconductor region.

5. The light-emitting device of claim 1, further comprising an array of VCSELs that includes the first VCSEL and is formed from the first set of material layers.

6. The light-emitting device of claim 5, wherein each VCSEL in the array of VCSELs is electrically coupled to at least one other VCSEL in the array of VCSELs by at least one metal trace included in the light-emitting device.

7. The light-emitting device of claim 5, wherein the first photodiode is disposed between two VCSELs in the array of VCSELs.

8. The light-emitting device of claim 5, wherein the first photodiode is disposed in a center region of the array of VCSELs.

9. The light-emitting device of claim 1, further comprising an array of photodiodes that includes the first photodiode, wherein each photodiode of the array of photodiodes is formed at the surface of the portion of the semiconductor substrate

10. The light-emitting device of claim 9, further comprising an array of VCSELs that includes the first VCSEL and is formed from the first set of material layers, wherein the first photodiode is disposed between two VCSELs of the array of VCSELS and a second photodiode of the array of photodiodes is disposed at an edge region of the array of VCSELs.

11. The light-emitting device of claim 9, further comprising an array of VCSELs that includes the first VCSEL and is formed from the first set of material layers, wherein the first photodiode is disposed in a center region of the array of VCSELs.

12. The light-emitting device of claim 1, wherein the set of material layers comprises a set of epitaxially grown layers.

13. The light-emitting device of claim 1, further comprising at least one metal trace that electrically coupled to the portion of the semiconductor substrate.

14. A method of forming a light-emitting device, the method comprising:
forming a set of material layers on a semiconductor substrate of a first conductivity type, wherein the set of material layers includes a laser cavity;
etching a portion of the set of material layers to expose a surface of an edge region of the semiconductor substrate;
performing a first ion implantation on the edge region to form an intrinsic semiconductor region from the edge region;
performing a second ion implantation on a portion of the intrinsic semiconductor region to form a semiconductor region of a second conductivity type; and
separating a die portion from the semiconductor substrate, wherein the die portion includes the laser cavity, the intrinsic semiconductor region, and the semiconductor region of a second conductivity type.

15. The method of claim 14, further comprising performing a third ion implantation on the set of material layers to isolate the laser cavity included in the set of material layers.

16. The method of claim 14, wherein forming the set of material layers on the semiconductor substrate comprises epitaxially growing the set of material layers on the semiconductor substrate.

17. The method of claim 14, further comprising, prior to separating the die portion from the semiconductor substrate, forming a first electrical connection to a top region of the set of material layers and a second electrical connection to the semiconductor region of the second conductivity type.

18. The method of claim 17, wherein the top region of the set of material layers comprises a top mirror layer of a vertical cavity surface-emitting laser (VCSEL) that is formed from the set of material layers.

19. The method of claim 17, wherein the second electrical connection is electrically coupled to at least one other semiconductor region of the second conductivity type that is included in the die portion.

20. The method of claim 14, wherein etching the portion of the set of material layers to expose the surface of the edge region of the semiconductor substrate comprises etching a plurality of portions of the set of materials so that a plurality of edge regions of the semiconductor substrate associated with the die portion are exposed.
